(19) United States
(12) Patent Application Publication
(10) Pub. No.: US 2006/0214567 A1
(43) Pub. Date: Sep. 28, 2006

(54) Organic electroluminescent element

(76) Inventors: Yongchun Luo, Kusatsu-shi (JP); Naomi Nagai, Otsu-shi (JP); Nobuhito Miura, Otsu-shi (JP); Naganori Tsutsui, Yasu-shi (JP)

Correspondence Address: STEPTOE & JOHNSON LLP, 1330 CONNECTICUT AVENUE, N.W., WASHINGTON, DC, 20036, US

(21) Appl. No.: 11/385,681

(22) Filed: Mar. 22, 2006

(30) Foreign Application Priority Data
Mar. 25, 2005 (JP) JP 20-8940

(51) Int. Cl. H01J 1/62

(52) U.S. Cl. 313/504

(57) ABSTRACT

The present invention provides a top emission-type organic EL element with low resistance, whose upper electrode transmits visible light. The organic EL element includes an electron-transport layer, a light-emitting layer, a hole-transport layer and an upper electrode functioning as an anode formed in that order on a lower electrode functioning as a cathode. The upper electrode, which transmits visible light, includes a transparent electrode layer, a metal electrode layer and a transparent electrode layer, layered in that order from the lower electrode side.

### BACKGROUND OF THE INVENTION

1. Field of the Invention

The present invention relates to organic EL (electroluminescent) elements.

2. Description of the Related Art

Organic electroluminescent elements are self-emitting elements, so that they have excellent visibility and there are high expectations regarding their application not only in flat displays but also as illumination devices. Such organic EL elements ordinarily have a bottom emission structure, in which a transparent electrode made of ITO (indium tin oxide) or the like serving as the anode is provided on a substrate, a light-emitting layer made of an organic EL material is layered on top thereof, and a layer made of a metal film serving as the cathode is arranged on top of the light-emitting layer, and the emitted light is emitted from the lower electrode side. In contrast to this ordinary configuration, there is also the top emission structure, in which a transparent electrode of ITO or the like serves as the upper electrode, a light-emitting layer is arranged below that, and finally a lower electrode is arranged below the light-emitting layer, and the light from the light-emitting layer is retrieved from the upper electrode side.

Furthermore, known methods for driving pixels in the case that organic EL elements are used in a display device include the passive matrix method and the active matrix method. The active matrix method is superior with regard to the fact that individual pixels can be driven independently and simultaneously. To employ the active matrix method, it is necessary to form on a lower substrate TFTs (thin film transistors) for driving the individual pixels, in case that a display device with a large screen is manufactured. Here, in the bottom emission structure, when the TFTs are formed on the lower substrate, the presence of the TFTs decreases the efficiency with which light can be retrieved. If the top emission structure is employed, the light-emission efficiency will not decrease even when TFTs are formed on the lower substrate.

See “Organic EL Materials and Displays”, Junji Kido ed., CM Publishing Company.

However, when a display device with a large display screen is provided with top emission organic EL elements and the active matrix method is employed, then the wiring on the upper electrodes becomes long, and it becomes necessary to lower the resistance value of the wiring. On the other hand, due to the top emission structure, the upper electrodes have to be transparent. Thus, it is a problem to lower the resistance value of the upper electrodes and to fabricate low-resistance transparent electrodes while maintaining transparency.

### SUMMARY OF THE INVENTION

Accordingly, it is an object of the present invention to provide a top emission-type organic EL element having an upper electrode that has a low resistance and that transmits visible light.

In order to attain this object, an organic EL element according to a first aspect of the present invention includes an electron-transport layer, a light-emitting layer, a hole-transport layer and an upper electrode functioning as an anode formed in that order on a lower electrode functioning as a cathode;

wherein the upper electrode transmits visible light; and

wherein the upper electrode comprises a transparent electrode layer, a metal electrode layer and a transparent electrode layer layered in that order from the lower electrode side.

According to a second aspect of the present invention, in an organic EL element according to the first aspect,

the lower transparent electrode layer and the upper transparent electrode layer are made of ITO (indium tin oxide); and

the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum).

According to a third aspect of the present invention, in an organic EL element according to the first aspect,

the lower transparent electrode layer is made of ITO (indium tin oxide);

the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum); and

the upper transparent electrode layer is made of IZO (indium zinc oxide).

According to a fourth aspect of the present invention, in an organic EL element according to the first aspect,

the lower transparent electrode layer is made of IZO (indium zinc oxide);

the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum); and

the upper transparent electrode layer is made of ITO (indium tin oxide).

According to a fifth aspect of the present invention, in an organic EL element according to the first aspect,

the lower transparent electrode layer and the upper transparent electrode layer are made of IZO (indium zinc oxide);

the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum).

According to a sixth aspect of the present invention, in an organic EL element according to any of the first to fifth aspects,

the thickness of the lower transparent electrode layer is at least 50 Å and at most 1000 Å.

According to a seventh aspect of the present invention, in an organic EL element according to any of the first to fifth aspects,

the thickness of the lower transparent electrode layer is at least 100 Å and at most 500 Å.

According to an eighth aspect of the present invention, in an organic EL element according to any of the first to fifth aspects,

the thickness of the intermediate transparent metal layer is at least 10 Å and at most 200 Å.

According to a ninth aspect of the present invention, in an organic EL element according to any of the first to fifth aspects,

the thickness of the intermediate transparent metal layer is at least 30 Å and at most 150 Å.

According to a tenth aspect of the present invention, in an organic EL element according to any of the first to fifth aspects,

the thickness of the upper transparent electrode layer is at least 100 Å and at most 2000 Å.

According to an eleventh aspect of the present invention, in an organic EL element according to any of the first to fifth aspects,

the thickness of the lower transparent electrode layer is at least 100 Å and at most 500 Å;

the thickness of the intermediate transparent metal layer is at least 30 Å and at most 150 Å; and

the thickness of the upper transparent electrode layer is at least 100 Å and at most 2000 Å.

According to a twelfth aspect of the present invention, in an organic EL element according to any of the first to fifth aspects,

the thickness of the lower transparent electrode layer is at least 50 Å and at most 1000 Å;

the thickness of the intermediate transparent metal layer is at least 10 Å and at most 200 Å; and

the thickness of the upper transparent electrode layer is at least 100 Å and at most 2000 Å.

An organic EL element according to a thirteenth aspect of the present invention includes a hole-transport layer, a light-emitting layer, an electron-transport layer and an upper electrode functioning as a cathode formed in that order on a lower electrode functioning as an anode;

wherein the upper electrode transmits visible light; and

wherein the upper electrode comprises a lower transparent electrode layer, an intermediate transparent electrode metal layer and an upper transparent electrode layer layered in that order from the lower electrode side.

According to a fourteenth aspect of the present invention, in an organic EL element according to the thirteenth aspect,

the lower transparent electrode layer and the upper transparent electrode layer are made of ITO (indium tin oxide); and

the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum).

According to a fifteenth aspect of the present invention, in an organic EL element according to the thirteenth aspect,

the lower transparent electrode layer is made of ITO (indium tin oxide);

the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum); and

the upper transparent electrode layer is made of IZO (indium zinc oxide).

According to a sixteenth aspect of the present invention, in an organic EL element according to the thirteenth aspect,

the lower transparent electrode layer is made of IZO (indium zinc oxide);

the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum); and

the upper transparent electrode layer is made of ITO (indium tin oxide).

According to a seventeenth aspect of the present invention, in an organic EL element according to the thirteenth aspect,

the lower transparent electrode layer and the upper transparent electrode layer are made of IZO (indium zinc oxide); and

the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum).

According to an eighteenth aspect of the present invention, in an organic EL element according to any of the thirteenth to seventeenth aspects,

the thickness of the lower transparent electrode layer is at least 50 Å and at most 1000 Å.

According to a nineteenth aspect of the present invention, in an organic EL element according to any of the thirteenth to seventeenth aspects,

the thickness of the lower transparent electrode layer is at least 100 Å and at most 500 Å.

According to a twentieth aspect of the present invention, in an organic EL element according to any of the thirteenth to seventeenth aspects,

the thickness of the intermediate transparent metal layer is at least 10 Å and at most 200 Å.

According to a twenty-first aspect of the present invention, in an organic EL element according to any of the thirteenth to seventeenth aspects,

the thickness of the intermediate transparent metal layer is at least 30 Å and at most 150 Å.

According to a twenty-second aspect of the present invention, in an organic EL element according to any of the thirteenth to seventeenth aspects,

the thickness of the upper transparent electrode layer is at least 100 Å and at most 2000 Å.

According to a twenty-third aspect of the present invention, in an organic EL element according to any of the thirteenth to seventeenth aspects,

the thickness of the lower transparent electrode layer is at least 100 Å and at most 500 Å;

the thickness of the intermediate transparent metal layer is at least 30 Å and at most 150 Å; and

the thickness of the upper transparent electrode layer is at least 100 Å and at most 2000 Å.

According to a twenty-fourth aspect of the present invention, in an organic EL element according to any of the thirteenth to seventeenth aspects,

the thickness of the lower transparent electrode layer is at least 50 Å and at most 1000 Å;

the thickness of the intermediate transparent metal layer is at least 10 Å and at most 200 Å; and

the thickness of the upper transparent electrode layer is at least 100 Å and at most 2000 Å.

With the first aspect of the present invention, in an organic EL element of the top emission-type, in which light is retrieved from an upper electrode functioning as an anode, the resistance of the upper electrode can be reduced by about one order of magnitude, so that an organic EL element of the top emission-type can be formed as a surface light source having a large surface area, and even when light of high luminance is emitted, the amount of heat generated can be reduced and the problem of cracks occurring in the upper transparent electrode can be solved.

Furthermore, also with the second to eleventh aspects of the present invention, the same effects as with the first aspect of the invention can be achieved.

With the twelfth aspect of the present invention, in addition to achieving the same effects as with the first aspect of the invention, it is possible to reduce the deterioration of transparency.

With the thirteenth aspect of the present invention, in an organic EL element of the top emission-type, in which light is retrieved from an upper electrode functioning as a cathode, the resistance of the upper electrode can be reduced by about one order of magnitude, so that an organic EL element of the top emission-type can be formed as a surface light source having a large surface area, and even when light of high luminance is emitted, the amount of heat generated can be reduced and the problem of cracks occurring in the upper transparent electrode can be solved.

Furthermore, also with the fourteenth to twenty-second aspects of the present invention, the same effects as with the thirteenth aspect of the invention can be achieved.

With the twenty-third aspect of the present invention, in addition to achieving the same effects as with the thirteenth aspect of the invention, it is possible to reduce the deterioration of transparency.

### BRIEF DESCRIPTION OF THE DRAWINGS

FIG. 1 is a cross-sectional view showing an outline of the configuration of an organic EL element according to Embodiment 1.

FIG. 2 is a cross-sectional view showing an outline of the configuration of an organic EL element according to Embodiment 2.

FIG. 3 is an image of an organic EL element in which cracks have actually occurred.

### PREFERRED EMBODIMENTS OF THE INVENTION

The following is a description of preferred embodiments of the invention, with reference to the accompanying drawings.

### Embodiment 1

In a top emission-type organic EL element according to Embodiment 1, the lower electrode serves as the anode, and the upper electrode is a transparent electrode with a triple-layer structure functioning as the cathode. This is described in the following, with reference to the drawings.

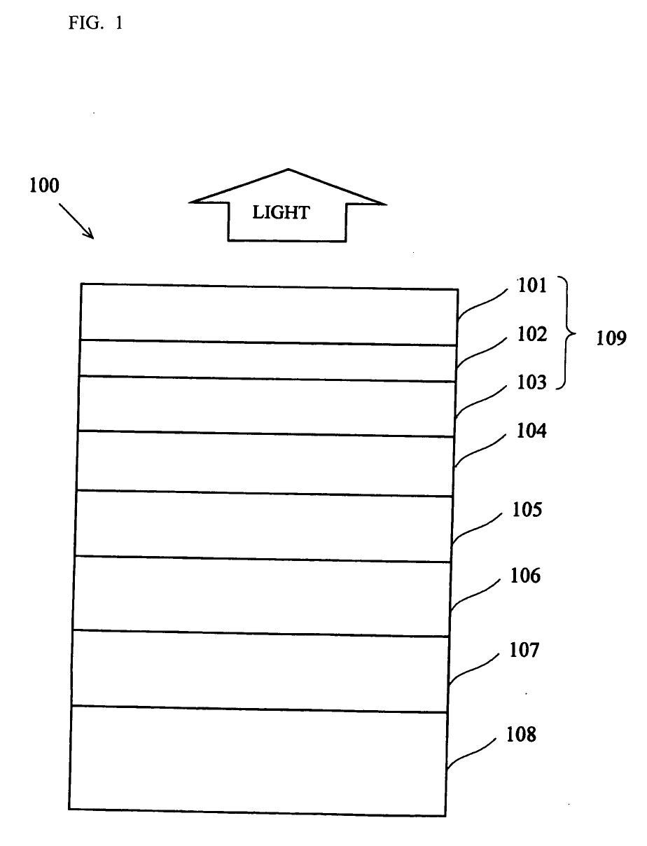

FIG. 1 is a cross-sectional view showing an outline of the configuration of an organic EL element according to Embodiment 1.

In FIG. 1, numeral 100 denotes a top emission-type organic EL element according to Embodiment 1. Numeral 108 denotes a substrate. Numeral 107 denotes a lower electrode functioning as an anode. Numeral 106 denotes a hole-transport layer. Numeral 105 denotes a light-emitting layer. Numeral 104 denotes an electron-transport layer. Numeral 109 denotes an upper electrode serving as a cathode. Numeral 103 denotes a lower transparent electrode layer. Numeral 102 denotes an intermediate transparent electrode metal layer. Numeral 101 denotes an upper transparent electrode layer.

In the organic EL element of Embodiment 1, a lower electrode 107 functioning as the anode is formed on the substrate 108. The lower electrode 107 is made by sputtering a film of ITO or IZO. The hole-transport layer 106, the light-emitting layer 105 and the electron-transport layer 104, which are made of organic EL materials, are formed on the lower electrode 107. The hole-transport layer 106, the light-emitting layer 105 and the electron-transport layer 104 are made of a hole-transporting material, a fluorescent dye and an electron-transporting material, which are used for ordinary organic EL elements. The upper electrode 109 is formed on the electron-transport layer 104. The upper electrode 109 has a triple-layer structure, in which the lower transparent electrode layer 103, the intermediate transparent electrode metal layer 102 and the upper transparent electrode layer 101 are layered in that order from the lower electrode side. The main characteristic feature of the organic EL element of this embodiment is the configuration of this upper electrode. The lower transparent electrode layer 103 is made by sputtering a film of ITO or IZO. The thickness of this lower transparent electrode layer 103 is 50 Å to 1000 Å, preferably 100 Å to 500 Å. Furthermore, the intermediate transparent electrode metal layer 102 arranged on top thereof is made by sputtering a film of at least one metal selected from the group consisting of Al (aluminum), Ag (silver), Au (gold), Cu (copper), Mo (molybdenum), Cr (chromium), Ni (nickel), Pt (platinum), Ti (titanium) and Ta (tantalum). The thickness of this intermediate transparent electrode metal layer 102 is 10 Å to 200 Å, preferably 30 Å to 150 Å. The upper transparent electrode layer 101 arranged on top thereof is made by sputtering a film of ITO or IZO. The thickness of this upper transparent electrode layer 101 is 100 Å to 2000 Å.

### Effect and Working Examples of Embodiment 1

By providing the upper electrode with a triple-layer structure as in Embodiment 1, it is possible to considerably reduce the electrical resistance while suppressing the deterioration of the transparency to a minimum. Table 1 shows a comparison of the resistance values of upper transparent electrodes with an ordinary single-layer structure and of upper transparent electrodes according to Working Example 1 and Working Example 2 of the present invention.

| | | Structure of Upper | Thickness of | Sheet |
|---|---|---|---|---|
| | | Electrode | Metal Film | Resistance (Ω/□) |
| A1 | Working | IZO/Ag/IZO | Ag: 100 Å | 6.3 |
| | Example 1 | | | |
| A2 | Comp. | IZO | | 48.7 |
| | Example 1 | | | |
| B1 | Working | ITO/Ag/ITO | Ag: 100 Å | 4.8 |
| | Example 2 | | | |
| B2 | Comp. | ITO | | 36.9 |
| | Example 2 | | | |

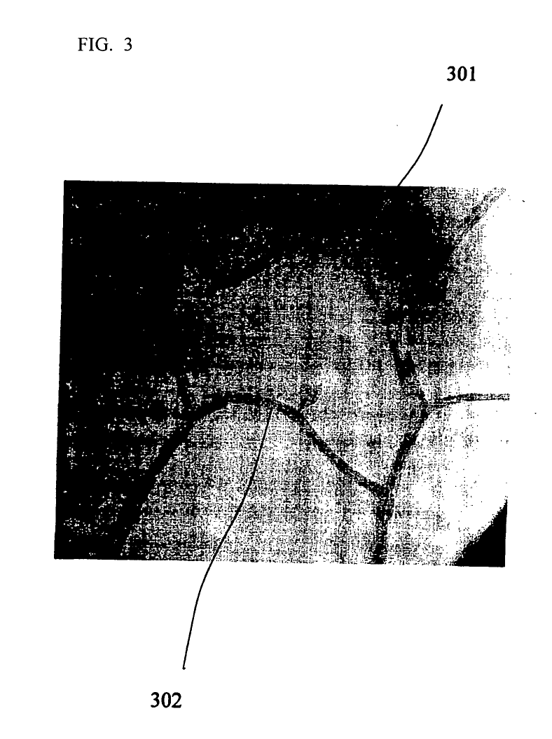

In Working Example 1, the lower transparent electrode layer 103 is made of IZO, the intermediate transparent electrode metal layer 102 is made of Ag and the upper transparent electrode layer 101 is made of IZO. In Working Example 2, the lower transparent electrode layer 103 is made of ITO, the intermediate transparent electrode metal layer 102 is made of Ag and the upper transparent electrode layer 101 is made of ITO. Row Al shows the sheet resistance of Working Example 1 and row A2 shows the sheet resistance of Comparative Example 1 (where the upper electrode has a single-layer structure made of IZO), which corresponds to Working Example 1. Similarly, row B1 shows the sheet resistance of Working Example 2 and row B2 shows the sheet resistance of Comparative Example 2 (where the upper electrode has a single-layer structure made of ITO), which corresponds to Working Example 2. As shown in Table 1, in Working Example 1, the sheet resistance for the case of Comparative Example 1 is 48.7 Ω/□, whereas the sheet resistance of the upper electrode of Working Example 1 is 6.3 Ω/□, so that the resistance value is about 13% of that of the Comparative Example 1. Also in Working Example 2, the sheet resistance for the case of Comparative Example 2 is 36.9 Ω/□, whereas the sheet resistance of the upper electrode of Working Example 2 is 4.8 Ω/□, so that the resistance value is about 13% of that of the Comparative Example 2. Thus, by employing a triple-layer structure according to Embodiment 1 for the upper electrode, it is possible to considerably reduce the resistance value of the upper electrode. When an organic EL element with a conventional upper electrode structure emits organic EL light with high luminance, cracks occur in the transparent electrode, due to problems regarding the dissipation of heat and the fact that a large current flows, whereas it is possible to prevent the occurrence of such cracks by employing an upper electrode with the triple-layer structure according to Embodiment 1. FIG. 3 is an image of an organic EL element with a conventional single-layer structure made of ITO or IZO in which cracks have actually occurred. Numerals 301 and 302 denote the cracks.

If an organic EL element of the top emission type is used as a surface light source with a larger surface area, then it is essential that the resistance of the transparent electrode is lowered. By employing the organic EL element of Embodiment 1, it is possible to realize such a transparent electrode with a low resistance, so that it becomes possible to increase the surface area of top emission-type organic EL elements serving as a surface light source.

### Embodiment 2

In a top emission-type organic EL element according to Embodiment 2, conversely to Embodiment 1, the lower electrode serves as the cathode, and the upper electrode is a transparent electrode with a triple-layer structure functioning as the anode. This is described in the following, with reference to the drawings.

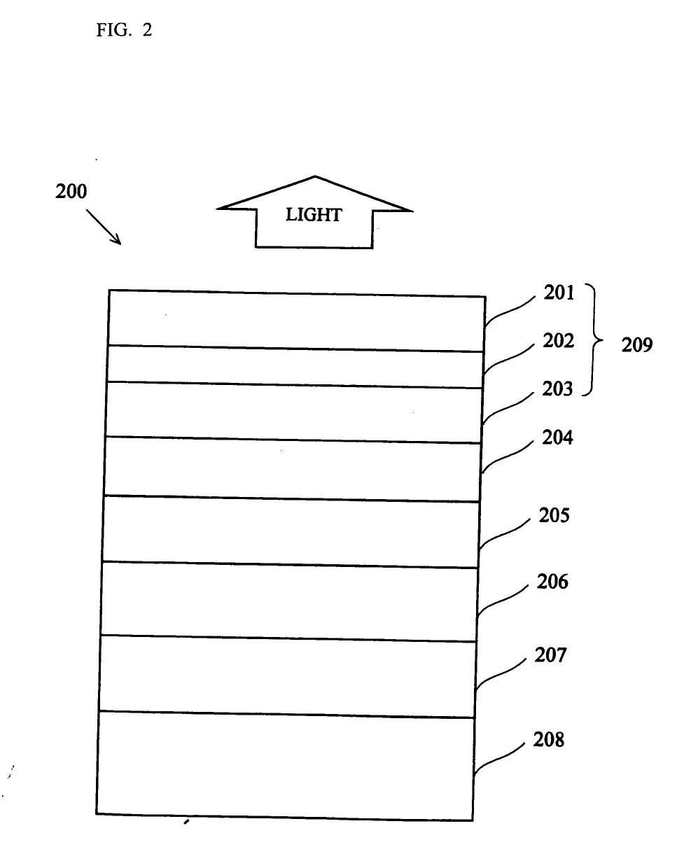

FIG. 2 is a cross-sectional view showing an outline of the configuration of an organic EL element according to Embodiment 2.

In FIG. 2, numeral 200 denotes a top emission-type organic EL element according to Embodiment 2. Numeral 208 denotes a substrate. Numeral 207 denotes a lower electrode functioning as a cathode. Numeral 206 denotes an electron-transport layer. Numeral 205 denotes a light-emitting layer. Numeral 204 denotes a hole-transport layer. Numeral 209 denotes an upper electrode serving as an anode. Numeral 203 denotes a lower transparent electrode layer. Numeral 202 denotes an intermediate transparent electrode metal layer. Numeral 201 denotes an upper transparent electrode layer.

In the organic EL element of Embodiment 2, a lower electrode 207 functioning as the cathode is formed on the substrate 208. The lower electrode 207 is made by sputtering or vapor deposition of a film comprising at least one of the group consisting of Al (aluminum), Ag (silver), Cr (chromium), Ni (nickel), Ti (titanium), Ta (tantalum), ITO or IZO. The electron-transport layer 206, the light-emitting layer 205 and the hole-transport layer 204, which are made of organic EL materials, are formed on the lower electrode 207. The electron-transport layer 206, the light-emitting layer 205 and the hole-transport layer 204 are made of a hole-transporting material, an electron-transporting material and a fluorescent dye, which are used for ordinary organic EL elements. The upper electrode 209 is formed on the hole-transport layer 204. The upper electrode 209 has a triple-layer structure, in which the lower transparent electrode layer 203, the intermediate transparent electrode metal layer 202 and the upper transparent electrode layer 201 are layered in that order from the lower electrode side. The main characteristic feature of the organic EL element of this Embodiment 2 is the configuration of this upper electrode, as in Embodiment 1. The lower transparent electrode layer 203 is made by sputtering a film of ITO or IZO. The thickness of this lower transparent electrode layer 203 is 50 Å to 1000 Å, preferably 100 Å to 500 Å. Furthermore, the intermediate transparent electrode metal layer 202 arranged on top thereof is made by sputtering a film of at least one metal selected from the group consisting of Al (aluminum), Ag (silver), Au (gold), Cu (copper), Mo (molybdenum), Cr (chromium), Ni (nickel), Pt (platinum), Ti (titanium) and Ta (tantalum) on top thereof. The thickness of this intermediate transparent electrode metal layer 202 is 10 Å to 200 Å, preferably 30 Å to 150 Å. The upper transparent electrode layer 201 arranged on top thereof is made by sputtering a film of ITO or IZO. The thickness of this upper transparent electrode layer 201 is 100 Å to 2000 Å.

### Effect and Working Examples of embodiment 2

Also in the organic EL element of Embodiment 2, as in Embodiment 1, by providing the upper electrode with a triple-layer structure, it is possible to considerably reduce the electrical resistance while suppressing the deterioration of the transparency to a minimum. Thus, the same effects as in Embodiment 1 are attained.

What is claimed is:

1. An organic EL element comprising an electron-transport layer, a light-emitting layer, a hole-transport layer and an upper electrode functioning as an anode formed in that order on a lower electrode functioning as a cathode,
wherein the upper electrode transmits visible light,
wherein the upper electrode comprises a transparent electrode layer (also referred to as “lower transparent electrode layer” below), a metal electrode layer (also referred to as “intermediate transparent electrode metal layer” below) and a transparent electrode layer (also referred to as “upper transparent electrode layer” below) layered in that order from the lower electrode side.

2. The organic EL element according to claim 1,
wherein the lower transparent electrode layer and the upper transparent electrode layer are made of ITO (indium tin oxide); and
wherein the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum).

3. The organic EL element according to claim 1,
wherein the lower transparent electrode layer is made of ITO (indium tin oxide);
wherein the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum); and
wherein the upper transparent electrode layer is made of IZO (indium zinc oxide).

4. The organic EL element according to claim 1,
wherein the lower transparent electrode layer is made of IZO (indium zinc oxide);
wherein the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum); and
wherein the upper transparent electrode layer is made of ITO (indium tin oxide).

5. The organic EL element according to claim 1,
wherein the lower transparent electrode layer and the upper transparent electrode layer are made of IZO (indium zinc oxide);
wherein the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum).

6. The organic EL element according to claim 1,
wherein the thickness of the lower transparent electrode layer is at least 50 Å and at most 1000 Å.

7. The organic EL element according to claim 1,
wherein the thickness of the lower transparent electrode layer is at least 100 Å and at most 500 Å.

8. The organic EL element according to claim 1,
wherein the thickness of the intermediate transparent metal layer is at least 10 Å and at most 200 Å.

9. The organic EL element according to claim 1,
wherein the thickness of the intermediate transparent metal layer is at least 30 Å and at most 150 Å.

10. The organic EL element according to claim 1,
wherein the thickness of the upper transparent electrode layer is at least 100 Å and at most 2000 Å.

11. The organic EL element according to any of claims 1 to 5,
wherein the thickness of the lower transparent electrode layer is at least 100 Å and at most 500 Å;
wherein the thickness of the intermediate transparent metal layer is at least 30 Å and at most 150 Å; and
wherein the thickness of the upper transparent electrode layer is at least 100 Å and at most 2000 Å.

12. The organic EL element according to any of claims 1 to 5,
wherein the thickness of the lower transparent electrode layer is at least 50 Å and at most 1000 Å;
wherein the thickness of the intermediate transparent metal layer is at least 10 Å and at most 200 Å; and
wherein the thickness of the upper transparent electrode layer is at least 100 Å and at most 2000 Å.

13. An organic EL element comprising a hole-transport layer, a light-emitting layer, an electron-transport layer and an upper electrode functioning as an cathode formed in that order on a lower electrode functioning as a anode;
wherein the upper electrode transmits visible light; and
wherein the upper electrode comprises a lower transparent electrode layer, an intermediate transparent electrode metal layer and an upper transparent electrode layer layered in that order from the lower electrode side.

14. The organic EL element according to claim 13,
wherein the lower transparent electrode layer and the upper transparent electrode layer are made of ITO (indium tin oxide); and
wherein the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum).

15. The organic EL element according to claim 13,
wherein the lower transparent electrode layer is made of ITO (indium tin oxide);
wherein the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum); and
wherein the upper transparent electrode layer is made of IZO (indium zinc oxide).

16. The organic EL element according to claim 13,
wherein the lower transparent electrode layer is made of IZO (indium zinc oxide);
wherein the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum); and
wherein the upper transparent electrode layer is made of ITO (indium tin oxide).

17. The organic EL element according to claim 13,
wherein the lower transparent electrode layer and the upper transparent electrode layer are made of IZO (indium zinc oxide); and
wherein the intermediate transparent metal layer is made of at least one material selected from the group consisting of Al (aluminum), Ag (silver), Au (gold), Cu (copper), Mo (molybdenum), Cr (chromium), Ni (nickel), Pt (platinum), Ti (titanium) and Ta (tantalum).

18. The organic EL element according to claim 13,
wherein the thickness of the lower transparent electrode layer is at least 50 Å and at most 1000 Å.

19. The organic EL element according to claim 13,
wherein the thickness of the lower transparent electrode layer is at least 100 Å and at most 500 Å.

20. The organic EL element according to claim 13,
wherein the thickness of the intermediate transparent metal layer is at least 10 Å and at most 200 Å.

21. The organic EL element according to claim 13,
wherein the thickness of the intermediate transparent metal layer is at least 30 Å and at most 150 Å.

22. The organic EL element according to claim 13,
wherein the thickness of the upper transparent electrode layer is at least 100 Å and at most 2000 Å.

23. The organic EL element according to any of claims 13 to 17,
wherein the thickness of the lower transparent electrode layer is at least 100 Å and at most 500 Å;
wherein the thickness of the intermediate transparent metal layer is at least 30 Å and at most 150 Å; and
wherein the thickness of the upper transparent electrode layer is at least 100 Å and at most 2000 Å.

24. The organic EL element according to any of claims 13 to 17,
wherein the thickness of the lower transparent electrode layer is at least 50 Å and at most 1000 Å;
wherein the thickness of the intermediate transparent metal layer is at least 10 Å and at most 200 Å; and
wherein the thickness of the upper transparent electrode layer is at least 100 Å and at most 2000 Å.
